(19) United States
(12) Patent Application Publication
(10) Pub. No.: US 2013/0061542 A1
(43) Pub. Date: Mar. 14, 2013

(54) PHOTOVOLTAIC WINDOW ASSEMBLY WITH SOLAR CONTROL PROPERTIES

(71) Applicant: Stephen E. Weidner, Sylvania, OH (US)

(72) Inventor: Stephen E. Weidner, Sylvania, OH (US)

(73) Assignee: PILKINGTON GROUP LIMITED, NR. ORMSKIRK, LANCASHIRE (GB)

(21) Appl. No.: 13/261,442

(22) PCT Filed: Mar. 30, 2011
(86) PCT No.: PCT/US11/00568

§ 371 Date: Nov. 17, 2012

Related U.S. Application Data
(60) Provisional application No. 61/319,635, filed on Mar. 31, 2010.

(51) Int. Cl. F24J 2/52; E04B 2/88; H01L 31/0203

(52) U.S. Cl. 52/173.3; 136/259

(57) ABSTRACT

A photovoltaic window assembly is provided. The photovoltaic window assembly includes a photovoltaic element, a solar control coating, and a space. The solar control coating is positioned adjacent the photovoltaic element. The space located immediately adjacent a surface of the solar control coating. The space is either between the photovoltaic element and the solar control coating or on a side of the solar control coating opposite the photovoltaic element. Additional embodiments of the photovoltaic window assembly are also provided.

### BACKGROUND OF THE INVENTION

The present invention relates to a multi-functional window assembly. More particularly, the invention relates to a building integrated photovoltaic window assembly.

Photovoltaic devices are known to be disposed in fields or upon rooftops to generate electrical energy. However, most of these photovoltaic devices are not suitable in a window unit because they are opaque.

U.S. Pat. No. 6,646,196, the '196 patent, discloses the use of photovoltaic cells for providing power to electrochromic coatings in a window unit. When provided power from the photovoltaic cells, the electrochromic coatings can be changed from a transparent to an opaque state. Thus, the electrochromic coatings can be controlled to provide variable light transmittance. Also, in their opaque state, the electrochromic coatings can block solar radiation.

However, these window units have several drawbacks. For instance, the electrochromic elements are expensive and consume the electrical energy generated by the photovoltaic element. As such, the cost of these window units is high and the electrical energy generated by them may not be used for other purposes. Also, in order for the photovoltaic cells to provide enough electrical energy during low light conditions to control the electrochromic elements, these window units are only suitable for integration into the south-facing portions of a building's facade. Furthermore, in the preferred configuration disclosed by the '196 patent, the photovoltaic cells are positioned along only the edge portions of the window unit. This configuration reduces the energy density of the window unit and is not acceptable for architectural applications.

Therefore, a need exists for a photovoltaic window assembly which is aesthetically pleasing, can be utilized on all faces of a building facade, generates electrical energy at a high density and does not require said energy to regulate the optical and solar control properties of the unit.

### BRIEF SUMMARY OF THE INVENTION

The present invention relates to an improved photovoltaic window assembly. Through utilization of a photovoltaic element and a solar control coating, the photovoltaic window assembly provides thermal solar control and utilizes solar radiation which contacts the window assembly to create electrical energy.

The photovoltaic window assembly comprises the photovoltaic element, the solar control coating, and a space. The solar control coating is positioned adjacent the photovoltaic element. The space is located immediately adjacent a surface of the solar control coating, wherein the space is either between the photovoltaic element and the solar control coating or on a side of the solar control coating opposite the photovoltaic element.

In a more particular embodiment, the photovoltaic window assembly comprises a laminate structure. The laminate structure comprises at least a first pane and a second pane of a transparent dielectric substrate material. Each pane has a first and a second major surface. The first pane has disposed on one or both of the major surfaces thereof, a functional thin-film coating. One of the functional thin-film coatings comprises an electrically conductive layer. The second pane has disposed on one or both of the major surfaces thereof, a functional thin-film coating. One of the functional thin-film coatings comprises a semiconductor layer. Disposed between the first and second panes is an electrolytic material, on one surface of which is disposed a chromophoric material, the foregoing arranged so as to function as a photovoltaic element.

Proximate and in a parallel, spaced apart relationship with the laminate structure, is at least a third pane of a transparent dielectric substrate material. The at least a third pane has two major surfaces. A functional thin-film coating is disposed on one or both of the major surfaces of the at least third pane. At least one of the functional thin-film coatings comprises a solar control coating. A spacer element and a space of a predetermined width separates the at least third pane of transparent dielectric substrate material from the laminate structure.

In another embodiment, the photovoltaic window assembly comprises a laminate structure. The laminate structure comprises at least a first pane and a second pane of a transparent dielectric substrate material. Each pane has a first and a second major surface. The first pane has disposed on one or both of the major surfaces thereof, a functional thin-film coating. One of the functional thin-film coatings comprises an electrically conductive layer. The second pane has disposed on each major surface a functional thin-film coating. One of the functional thin-film coatings comprises a semiconductor layer and one of the functional coatings comprises a solar control coating. Disposed between the first and second panes is an electrolytic material, on one surface of which is disposed a chromophoric material, the foregoing arranged so as to function as a photovoltaic element.

### BRIEF DESCRIPTION OF THE SEVERAL VIEWS OF THE DRAWINGS

FIG. 1 shows a cross-sectional view of a photovoltaic window assembly; and

FIG. 2 shows a cross-sectional view of another photovoltaic window assembly.

### DETAILED DESCRIPTION OF THE INVENTION

It is to be understood that the invention may assume various alternative orientations and step sequences, except where expressly stated to the contrary. It should also be appreciated that the specific embodiments illustrated in and described in the following specification are simply exemplary embodiments of the inventive concepts defined in the appended claims.

The present invention relates to a photovoltaic (PV) window assembly 10, preferably utilized as a component of a building facade or a glazing system.

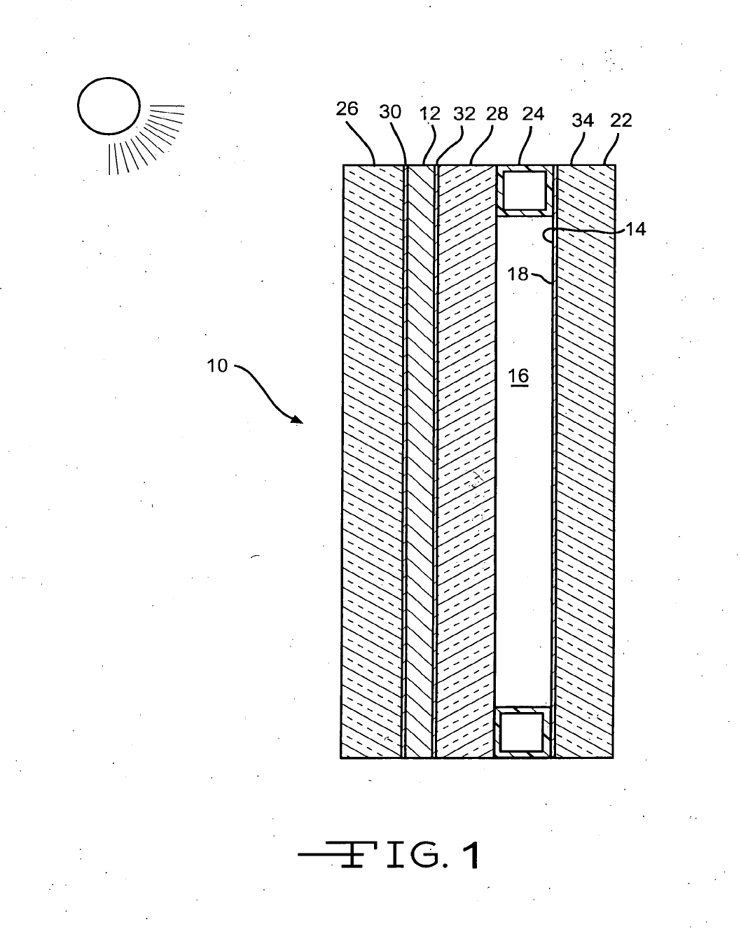

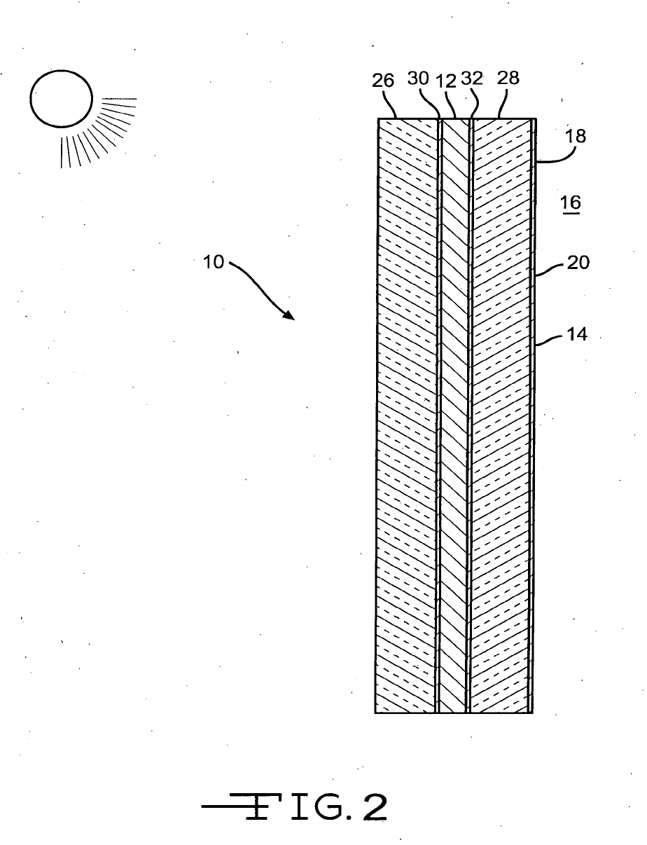

The PV window assembly 10 has thermal solar control properties and utilizes solar radiation which contacts the window assembly 10 to create electrical energy. Thus, while not depicted in the embodiments of FIGS. 1 and 2, the PV window assembly 10 may also require peripheral seals, electrical leads/connectors and electrical controllers.

The PV window assembly 10 comprises a PV element 12. The PV element 12 may have a laminate structure and is preferably a dye-sensitized PV element 12 also known as a regenerative photo-electrochemical (RPEC) element and/or a nano-dye solar cell. Hereafter, the PV element 12 will be referred to as of the RPEC type. In general terms, the RPEC PV element 12 utilized in the instant invention is described in, for example, U.S. Pat. Nos. 4,927,721, 6,297,900 and 7,649,140 which are incorporated by reference in their entirety.

The RPEC PV element 12 absorbs visible light and converts it into electrical energy. The RPEC PV element 12 does not convert all of the visible light it absorbs into electrical energy. Preferably, the RPEC PV element 12 has a conversion efficiency of 5% or more, and more preferably of 7% or more. However, the RPEC PV element 12 can provide electrical energy even under low light conditions. For example, the RPEC PV element 12 can produce electrical energy when the incident angle between the PV window assembly 10 and the sun is low, the window assembly 10 is shaded, and/or by absorbing the light generated by the building's interior lighting. The amount of visible light absorption may vary between RPEC PV elements suitable for use in the PV window assembly 10. Preferably, the RPEC PV elements utilized in practicing the instant invention will absorb about 80%-96% of the visible light that passes through them. Thus, a portion of the visible light that passes through the RPEC PV element 12 is unabsorbed. Advantageously, a portion of the visible light not absorbed by the RPEC PV element 12 is transmitted through the PV window assembly 10 and into the building. Preferably, a majority of visible light not absorbed by the RPEC PV element 12 is transmitted into the building.

It should be noted that in U.S. Pat. No. 6,297,900, the '900 patent, the electrical energy generated by the PV element is utilized to power and control an electrochromic (EC) element. The EC element provides solar control properties by darkening or lightening to allow more or less solar radiation to pass through a “smart window.” The smart window described in the '900 patent is relatively complex and presumably relatively expensive due to its complexity. However, because the solar control properties are regulated by controlling the EC element, the smart window consumes energy to save energy; i.e., the energy produced by the PV element in the '900 patent is consumed by the EC element to prevent or allow solar energy transmittance.

The present invention provides a simpler PV window assembly 10 than the window of the '900 patent. At the same time, the instant invention achieves the same or similar solar control properties as the window of the '900 patent, e.g. similar U-value and/or lower solar heat gain coefficient (SHGC), without consuming the electrical energy generated by the PV element 12. Therefore, the electrical energy generated by the PV element 12 is available to be utilized for other building functions, e.g., lighting, heating, cooling, etc.

Additionally, the PV window assembly 10 may effectively include panes having a larger surface area than those described in the '900 patent due to avoiding the problems associated with operation of EC elements. The advantages and performance characteristics of the RPEC PV element 12 described, above, contribute to allow the PV window assembly 10 to be utilized on all faces of the building facade or glazing system. Thus, the overall aesthetics of the building can be maintained to architectural standards.

As shown in FIGS. 1 and 2, the PV window assembly 10 comprises the PV element 12, a solar control coating 14, and a space 16. The solar control coating 14 is positioned adjacent the PV element 12. The space 16 is located immediately adjacent a surface 18 of the solar control coating 14. In certain embodiments, the space 16 is either between the PV element 12 and the solar control coating 14 or on a side 20 of the solar control coating 14 opposite the PV element 12.

The PV element 12 is of the RPEC type. The RPEC PV element 12 is preferably a laminate structure, comprising at least a first pane and a second pane of a transparent dielectric substrate material 26, 28. Each pane 26, 28 has a first and second major surface. The first pane 26 has disposed on one or both of the major surfaces thereof, a functional thin-film coating wherein one of the functional thin-film coatings comprises an electrically conductive layer 30. The second pane 28 has disposed on one or both of the major surfaces thereof, a functional thin-film coating, wherein one of the functional thin-film coatings comprises a semiconductor layer 32. Disposed between the first and second panes 26, 28 is an electrolytic material (not depicted), on one surface of which is disposed a chromophoric material (not depicted), the foregoing arranged so as to function as the RPEC PV element 12.

In an embodiment, like the one illustrated in FIG. 1, the PV window assembly 10 also comprises a thermal solar control element 22 and a spacer 24.

The thermal solar control element 22 is preferably proximate and in a parallel, spaced apart relationship with the laminate structure of the RPEC PV element 12. The thermal solar control element 22 includes at least a third pane of a transparent dielectric substrate material 34 having two major surfaces. The at least third pane 34, has disposed on one or both of the major surfaces thereof, a functional thin-film coating, wherein at least one of the functional thin-film coatings comprises the solar control coating 14. In an embodiment, the thermal solar control element 22 may be a coated glass article sold by Pilkington North America, Inc. under the trademarks ENERGY ADVANTAGE or SOLAR E, respectively. However, it should be appreciated that that other glass articles having solar control coatings disposed on one or both of their major surfaces could be utilized as the thermal solar control element 22 in the present invention.

The spacer 24 allows the space 16 to be created and maintained at a predetermined width and separates the at least third pane of transparent dielectric substrate material 34 from the laminate structure. The spacer 24 can be any conventional spacer which is known in the art and suitable for the purpose. In this embodiment, the space 16 can be filled with air or with an inert gas such as argon.

In an alternative embodiment shown in FIG. 2, the PV window assembly 10 comprises the RPEC PV element laminate structure. The laminate structure comprises the at least a first pane and the second pane 28 of a transparent dielectric substrate material 26, 28. Each pane 26, 28 has a first and second major surface. The first pane 26 has disposed on one or both of the major surfaces thereof, a functional thin-film coating. One of the functional thin-film coatings comprises an electrically conductive layer 30. The second pane 28 has disposed on both major surfaces functional thin-film coatings. One of the functional thin-film coatings comprises the semiconductor layer 32 and one of the functional coatings comprises the solar control coating 14. Disposed between the first and second panes 26, 28 is an electrolytic material, on one surface of which is disposed a chromophoric material, the foregoing arranged so as to function as the RPEC PV element 12.

As configured between the first and second panes 26, 28, the RPEC PV element 12 is substantially uniform in appearance. However, those skilled in the art would appreciate that the RPEC PV element 12 may have features for isolating and interconnecting portions of the RPEC PV element 12 that may be visible when examining the RPEC PV element 12 closely. Such features may include, for example, scribe lines. Nonetheless, when viewing objects appearing on either side of the RPEC PV element 12 they do not appear obscured or distorted. As such, the appearance of objects viewed through the PV window assembly 10 is not obscured or distorted.

Additionally, since the RPEC PV element 12 is disposed substantially equally between the first and second substrate panes, PV window assembly 10 has a high power density. Preferably, the power density of the PV window assembly 10 is above about 40 Watts/m². In an embodiment, the power density of the PV window assembly 10 is between about 41-64 Watts/m². In another embodiment, the power density of the PV window assembly 10 is above 64 Watts/m².

In certain embodiments, the first pane and second pane of dielectric substrate material 26, 28 are composed of glass. Preferably, the glass is substantially transparent to solar radiation, for example soda-lime-silica glass. In another embodiment, the glass is a minimally absorbing, low-iron soda-lime silica glass. It is preferred that when the first pane 26 and second pane 28 are composed of glass, that the glass is formed by the float glass process. In the embodiment depicted in FIG. 1, the at least a third pane of dielectric substrate material 34 is composed of glass. In this embodiment, it is preferred that the at least third pane 34 is soda-lime-silica glass which is substantially transparent to solar radiation and formed by the float glass process.

The solar control coating 14 may be of a low emissivity (low-E) or solar-E type. The solar control coating 14 provides the solar control properties of the PV window assembly 10. Particularly, the solar control coating 14 allows the PV window assembly 10 to reject solar energy in the summer, provide a low U-value in the winter, and reduce total solar energy transmittance. Specifically, the PV window assembly 10 has a U-value below 0.4 and a solar heat gain coefficient (SHGC) of between about 0.15-0.45.

It should be appreciated that PV window assemblies of the instant invention having either a low-E or solar-E type solar control coating may be integrated together in a building's facade or glazing system. However, the light transmission and solar control properties of the PV window assembly 10 may vary depending on which type of solar control coating is included in the PV window assembly 10. For example, depending on the type of solar control coating utilized in PV window assembly 10, the U-value for the photovoltaic window assembly 10 may be ≦0.35. Furthermore, when compared with the low-E solar control coating, the solar-E solar control coating may provide a further reduction in total solar energy transmittance through the PV window assembly 10 by absorbing a higher percentage of near infrared energy. As such, a PV window assembly 10 including a solar-E type solar control coating 14 preferably may have an SHGC <0.2. It should be noted that this performance improvement may be partially offset with a reduction in visible light transmission through the PV window assembly 10.

In an embodiment, the solar control coating 14 is included in a multilayered coating stack. In this embodiment, the solar control coating 14 can be, for example, a doped metal oxide layer. For example, when the solar control coating is of the low-E type, the multilayered coating stack could include a layer of tin oxide doped with fluorine (SnO₂:F). In this embodiment, the SnO₂:F functions as a low-E type solar control coating 14. Alternatively, the SnO₂:F could be replaced as the solar control coating 14 or used in combination with another solar control coating. For example, SnO₂:F could be replaced as the solar control coating 14 or used in combination with aluminum doped zinc oxide (ZnO:Al) or indium doped tin oxide (ITO). Furthermore, where the solar control coating 14 is of the solar-E type, SnO₂:F could be replaced or used in combination with tin oxide doped with antimony (SnO₂:Sb).

In the above-described embodiments, the multilayered coating stack could be similar to the multilayered coating stacks deposited on the glass articles sold under the trademarks ENERGY ADVANTAGE or SOLAR E by Pilkington North America, Inc. already disclosed, above. However, it should be appreciated that other multilayered coating stacks having a solar control coating can be utilized to practice the present invention. Also, the solar control coating 14 is not limited to doped metal oxide layers. For example, a titanium nitride layer may be utilized as a solar-E type solar control coating 14 in the PV window assembly 10.

It should be appreciated that the thickness of the solar control coating 14 may be adjusted to provide specific solar control and light transmittance properties. Furthermore, when the solar control coating 14 is included in a multilayered coating stack, the coating compositions and thicknesses of all the layers may be adjusted to provide specific solar control and light transmittance properties. Additionally, it should also be noted that coatings having other functionalities, such as varying degrees of reflectivity may be utilized in practicing the invention.

To form the solar control coating 14, a chemical vapor deposition (CVD) method may be employed. Preferably, the CVD of the solar control coating is practiced at atmospheric pressure. It should be appreciated that other deposition methods may be utilized to form the solar control coating 14, such as sputtering or sol-gel. For example, in the embodiment depicted in FIG. 2, while the solar control coating 14 may be deposited by any suitable method, it is preferable that the solar control coating 14 is deposited by a vacuum sputtering process.

Regardless of the process by which the solar control coating 14 is deposited, the PV window assembly 10 allows for acceptable visible light transmission. The amount of visible light transmitted through the PV window assembly 10 will be influenced by the absorption of the RPEC PV element 12, the composition of the transparent dielectric substrate material 26, 28, 34, and the configuration and composition of the solar control coating 14. As such, the embodiments of the PV window assembly 10 shown in FIGS. 1 and 2 may have a range of visible light transmission of about 0.4%-15%.

Since the PV window assembly 10 provides good solar control properties and visible light transmission, it may be utilized in any suitable manner to close an opening in a building. For example, the PV window assembly 10 may be used in transom-style windows, combining the present assembly with vision area units. The PV window assembly 10 is especially beneficial in vision areas of a building because it provides acceptable visible light transmission and glare control. The PV window assembly 10 may also be used in spandrel applications. In certain circumstances, it may be used alone as a glazing.

Utilizing the present invention in a building reduces the buildings U-value. The U-value or the overall heat transfer coefficient is inversely proportional to the thermal resistance of the building and is typical expressed in Btu/hr/sq-ft/° F. For the purposes of this application, U-value can be expressed as a measure of the heat gain or loss through the PV window assembly 10 due to the environmental differences between the outdoor air and indoor air. A lower U-value means that less heat is lost from the building's interior to its exterior resulting in savings in energy costs.

Utilizing the solar control coating 14 improves the solar control properties of the PV window assembly 10 in the summer and winter. The radiation energy, a component of the indirect gain from the PV window assembly 10 to the building's interior, is reduced under summer conditions with the solar control coating 14. This is noticed as a reduction in the total solar heat transmittance (TSHT). TSHT is defined as including solar energy transmitted directly through the PV window assembly 10, and the solar energy absorbed by the PV window assembly 10, and subsequently convected and thermally radiated inwardly. Further, SHGC is defined as the ratio of total solar heat gain through the PV window assembly 10 relative to the incident solar radiation. The major improvement in performance, however, occurs under winter conditions where the U-value of the PV window assembly 10 is reduced significantly with the solar control coating 14.

### EXAMPLES

The following examples are for illustrative purposes only and are not to be construed as a limitation on the invention.

Table 1 summarizes the optical, solar control, and power performance data for several embodiments of the PV window assembly of the present invention. The data was generated using the Lawrence Berkeley National Laboratory's Window 5.2 modeling program.

Examples 1-4 were configured as described, above, for the PV window assembly illustrated in FIG. 1. As such, the PV window assembly includes the RPEC PV element laminate structure and the thermal solar control element proximate and in a parallel, spaced apart relationship with the laminate structure.

The thermal solar control element of Examples 1, 3 and 4 included a low-E type solar control coating. The thermal solar control element of Example 2 included a solar-E type solar control coating. In Examples 1-4, the solar control coating was included in a multilayered coating stack. Specifically, the solar control coating of Examples 1, 3 and 4 was a layer of SnO₂:F having a thickness of approximately 3000 Å-3500 Å. Whereas, the solar control coating of Example 2 was a layer of SnO₂:Sb having a thickness of approximately 1700 Å-2000 Å. Additionally, in Example 2, a layer of SnO₂:F having a thickness of approximately 2000 Å-2400 Å was deposited over the SnO₂:Sb layer.

Examples 1, 3 and 4 were modeled using different RPEC PV elements. The RPEC PV elements of Examples 1, 3 and 4 absorb different percentages of visible light. The visible light absorption for the RPEC PV element of Example 1 was 91.2%. The visible light absorption for the RPEC PV element of Example 3 was 89.1%. The visible light absorption for the RPEC PV element of Example 4 was 82%. Examples 1 and 2 were modeled as having the same RPEC PV element. Therefore, the absorption for the RPEC PV element of Example 2 is 91.2%.

The power density of Examples 1-4 was calculated using an illumination of 1000 W/m², the visible light absorption for each RPEC PV element, and a conversion efficiency for each RPEC PV element of 5% and 7%, respectively. Power density is expressed in Watts/m². For Examples 1-4, Tvis is expressed as the percentage of the visible light transmitted through the PV window assembly and U-value is expressed in Btu/hr/sq-ft/° F.

Two Comparative Examples (C5, C5_{tinted}) are provided in Table 1. The Comparative Examples represent the same EC window unit. C5 represents the optical and solar control properties for the EC window unit before the EC element is darkened. C5_{tinted} represents the optical and solar control properties for the EC window unit after electrical energy is applied to the EC element and it darkens. The values listed in Table 1 were calculated using the Windows 5.2 modeling program. Each unit is in an IGU configuration and includes the EC element and a sheet of glass in a spaced apart parallel relationship with the EC element. The space between the EC element and the sheet of glass is filled with a gas mixture which is 90% argon.

The optical and solar control properties presented for C5 and C5_{tinted} in Table 1 are expressed in the same units as the optical and solar control properties of the PV window assemblies of Examples 1-4.

TABLE 1
Optical, Solar Control, and Power Performance

| Example | Tvis | U-value | SHGC | Power Density |
|---|---|---|---|---|
| 1 | .9 | .33 | .20 | 45.6/63.8 |
| 2 | .5 | .33 | .19 | 45.6/63.8 |
| 3 | 6.8 | .33 | .32 | 44.6/62.4 |
| 4 | 11.9 | .33 | .23 | 41/57.4 |
| C5 | 62 | .28 | .48 | N/A |
| C5_{tinted} | 3.5 | .28 | .09 | N/A |

As illustrated in Table 1, the PV window assembly of the present invention provides improved solar performance over the EC window unit before the EC element is darkened. Furthermore, the PV window assembly of the present invention provides similar solar control properties even when the EC element is darkened. However, the instant invention also has the added advantage of producing electrical energy and, without consuming said energy, regulating the optical and solar control properties of the window assembly.

The invention has been disclosed in what is considered to be its preferred embodiments. It must be understood, however, the specific embodiments are provided only for the purpose of illustration, and that the invention may be practiced otherwise than as specifically illustrated without departing from its spirit and scope. Accordingly, all suitable modifications and equivalents may be considered as falling within the scope of the invention as defined by the claims which follow.

1. A photovoltaic window assembly, comprising:
a photovoltaic element;
a solar control coating positioned adjacent the photovoltaic element; and
a space located immediately adjacent a surface of the solar control coating, wherein the space is either between the photovoltaic element and the solar control coating or on a side of the solar control coating opposite the photovoltaic element.

2. The photovoltaic window assembly of claim 1, wherein the photovoltaic element has a laminate structure.

3. The photovoltaic window assembly of claim 1, wherein the solar control coating is of the low-E or solar-E type.

4. The photovoltaic window assembly of claim 1, wherein the assembly has a visible light transmission of 0.4-15%.

5. The photovoltaic window assembly of claim 1, wherein the assembly has an SHGC of between 0.15-0.45.

6. The photovoltaic window assembly of claim 1, wherein the space is filled with air.

7. A photovoltaic window assembly comprising:
a laminate structure comprising:
at least a first pane and a second pane of a transparent dielectric substrate material;
each pane having a first and a second major surface;
the first pane having disposed on one or both of the major surfaces thereof, a functional thin-film coating, wherein one of the functional thin-film coatings comprises an electrically conductive layer;
the second pane having disposed on one or both of the major surfaces thereof, a functional thin-film coating, wherein one of the functional thin-film coatings comprises a semiconductor layer;
disposed between the first and second panes, is an electrolytic material, on one surface of which is disposed a chromophoric material, the foregoing arranged so as to function as a photovoltaic element;
proximate and in a parallel, spaced apart relationship with the laminate structure, at least a third pane of a transparent dielectric substrate material having two major surfaces, the at least third pane, having disposed on one or both of the major surfaces thereof, a functional thin-film coating, wherein at least one of the functional thin-film coatings comprises a solar control coating; and
a spacer element and a space of a predetermined width separates the at least third pane of transparent dielectric substrate material from the laminate structure.

8. The photovoltaic window assembly of claim 7, wherein the transparent dielectric substrate material is composed of glass.

9. The photovoltaic window assembly of claim 7, wherein the assembly is installed as a component of a building facade.

10. The photovoltaic window assembly of claim 7, wherein the assembly has a visible light transmission of between about 0.4-15%.

11. The photovoltaic window assembly of claim 7, wherein the solar control coating is of the low-E or solar-E type.

12. The photovoltaic window assembly of claim 7, wherein the photovoltaic element is of the RPEC type.

13. The photovoltaic window assembly of claim 7, wherein the assembly has a U-value of below 0.4.

14. The photovoltaic window assembly of claim 7, wherein the assembly has an SHGC of below 0.2.

15. A photovoltaic window assembly comprising:
a laminate structure comprising:
at least a first pane and a second pane of a transparent dielectric substrate material;
each pane having a first and a second major surface;
the first pane having disposed on one or both of the major surfaces thereof, a functional thin-film coating;
wherein one of the functional thin-film coating comprises an electrically conductive layer;
the second pane having disposed on both of the major surfaces thereof, a functional thin-film coating, wherein one of the functional thin-film coatings comprises a semiconductor layer and one of the functional coatings comprises a solar control coating;
disposed between the first and second panes, is an electrolytic material, on one surface of which is disposed a chromophoric material, the foregoing arranged so as to function as a photovoltaic element; and
wherein the PV window assembly is capable of providing thermal solar control and utilizing solar radiation which contacts the window assembly to create electrical energy.

16. The photovoltaic window assembly of claim 15, wherein the photovoltaic element is of the RPEC type.
